(19) United States
(12) Patent Application Publication
(10) Pub. No.: US 2017/0323963 A1
(43) Pub. Date: Nov. 9, 2017

(54) THIN CHANNEL REGION ON WIDE SUBFIN

(71) Applicant: INTEL CORPORATION, Santa Clara, CA (US)

(72) Inventors: Sanaz K. GARDNER, Hillsboro, OR (US); Willy RACHMADY, Beaverton, OR (US); Matthew V. METZ, Portland, OR (US); Gilbert DEWEY, Hillsboro, OR (US); Jack T. KAVALIEROS, Portland, OR (US); Chandra S. MOHAPATRA, Beaverton, OR (US); Anand S. MURTHY, Portland, OR (US); Nadia RAHHAL-ORABI, Hillsboro, OR (US); Nancy M. ZELICK, Portland, OR (US); Tahir GHANI, Portland, OR (US)

(21) Appl. No.: 15/528,802

(22) PCT Filed: Dec. 23, 2014
(86) PCT No.: PCT/US2014/072276

§ 371 Date: May 23, 2017

(51) Int. Cl. H01L 29/78; H01L 29/10; H01L 29/205; H01L 29/66

(52) U.S. Cl. CPC H01L 29/785; H01L 29/66818; H01L 29/1054; H01L 29/205

(57) ABSTRACT

An embodiment includes a device comprising: a fin structure including an upper portion and a lower portion, the upper portion having a bottom surface directly contacting an upper surface of the lower portion; wherein (a) the lower portion is included in a trench having an aspect ratio (depth to width) of at least 2:1; (b) the bottom surface has a bottom maximum width and the upper surface has an upper maximum width that is greater the bottom maximum width; (c) the bottom surface covers a middle portion of the upper surface but does not cover lateral portions of the upper surface; and (d) the upper portion includes an upper III-V material and the lower portion includes a lower III-V material different from the upper III-V material. Other embodiments are described herein.

### TECHNICAL FIELD

Embodiments of the invention are in the field of semiconductor devices and, in particular, non-planar transistors.

### BACKGROUND

A FinFET is a transistor built around a thin strip of semiconductor material (referred to as the “fin”). The transistor includes the standard field effect transistor (FET) nodes/components: a gate, a gate dielectric, a source region, and a drain region. The conductive channel of the device resides on the outer sides of the fin beneath the gate dielectric. Specifically, current runs along both “sidewalls” of the fin as well as along the top side of the fin. Because the conductive channel essentially resides along the three different outer, planar regions of the fin, such a FinFET is typically referred to as a “tri-gate” FinFET. Other types of FinFETs exist (such as “double-gate” FinFETs in which the conductive channel principally resides only along both sidewalls of the fin and not along the top side of the fin).

### BRIEF DESCRIPTION OF THE DRAWINGS

Features and advantages of embodiments of the present invention will become apparent from the appended claims, the following detailed description of one or more example embodiments, and the corresponding figures. Where considered appropriate, reference labels have been repeated among the figures to indicate corresponding or analogous elements.

FIG. 1 includes a method in an embodiment of the invention.

FIG. 2 includes an image of an embodiment of the invention.

FIGS. 3(a)-(f) show cross-sections of embodiments of the invention at various processing stages. FIG. 3(g) shows a top view of the device of FIG. 3(e).

### DETAILED DESCRIPTION

Reference will now be made to the drawings wherein like structures may be provided with like suffix reference designations. In order to show the structures of various embodiments more clearly, the drawings included herein are diagrammatic representations of semiconductor/circuit structures. Thus, the actual appearance of the fabricated integrated circuit structures, for example in a photomicrograph, may appear different while still incorporating the claimed structures of the illustrated embodiments. Moreover, the drawings may only show the structures useful to understand the illustrated embodiments. Additional structures known in the art may not have been included to maintain the clarity of the drawings. For example, not every layer of a semiconductor device is necessarily shown. “An embodiment”, “various embodiments” and the like indicate embodiment(s) so described may include particular features, structures, or characteristics, but not every embodiment necessarily includes the particular features, structures, or characteristics. Some embodiments may have some, all, or none of the features described for other embodiments. “First”, “second”, “third” and the like describe a common object and indicate different instances of like objects are being referred to. Such adjectives do not imply objects so described must be in a given sequence, either temporally, spatially, in ranking, or in any other manner. “Connected” may indicate elements are in direct physical or electrical contact with each other and “coupled” may indicate elements co-operate or interact with each other, but they may or may not be in direct physical or electrical contact.

Aspect ratio trench (ART) technology is sometimes used to form FinFETs. ART is based on threading dislocations that propagate upwards at a specific angle. In ART a trench is made with a high enough aspect ratio such that the defects terminate on the sidewall of the trench and any layer above the terminations is defect free. More specifically, ART includes trapping defects along the sidewall of a shallow trench isolation (STI) portion by making the height (H) of the trench larger than the width (W) of the trench such that H/W ratio is at least 1.50. This ratio gives the minimum limit for ART to block defects within a buffer layer.

ART trenches can be used to try and form thinner fins, which may exhibit improved electrostatics. However, Applicants have determined that using thinner and thinner trenches to form thinner and thinner fins can be problematic. For example, certain materials that are desirable for fins cannot grow well in thin trenches. For instance, InP is desirable for the subfin area (portion of the fin that is, for example, below the channel area) due to its high bandgap, which helps confine carriers to the channel and prevents or deters leakage current. However, Applicants have determined InP may be difficult to grow in ART trenches because the kinetics of InP epitaxial growth in narrow trenches is mass transfer limited (i.e., reaction is severely limited by the diffusion of reactants and products in and out of the trenches).

An embodiment remedies this problem and results in ultrathin fin profiles for improved electrostatics. Such fins may include InₓGa₁₋ₓAs, where x is between 0 and 1, in the upper portion of the fin and InP in the subfin area. In an embodiment, the ultrathin InGaAs fins are formed using a wet etch of InGaAs and reduce damage to InGaAs on fin sidewalls that normally occurs due to processing. An embodiment provides an ultra-narrow InGaAs fin on a wide-bandgap subfin InP layer, which achieves electrostatic control in scaled III-V transistors.

While “InGaAs” is often used herein, “InGaAs” includes InₓGa₁₋ₓAs where x is between 0 and 1 thereby including, in various embodiments, InAs and in other embodiments GaAs. Further, while InP is used often for a subfin portion, many other high bandgap materials will suffice such as, for example, GaAs, InₓAl₁₋ₓAs, GaP (e.g., InAlAs includes InₓAl₁₋ₓAs where x is between 0 and 1) and the like.

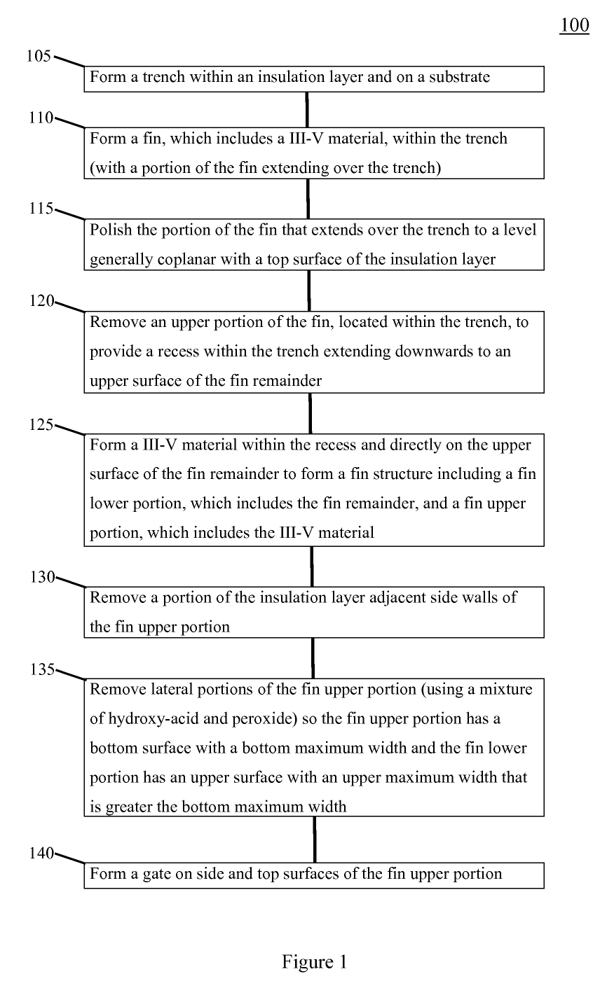

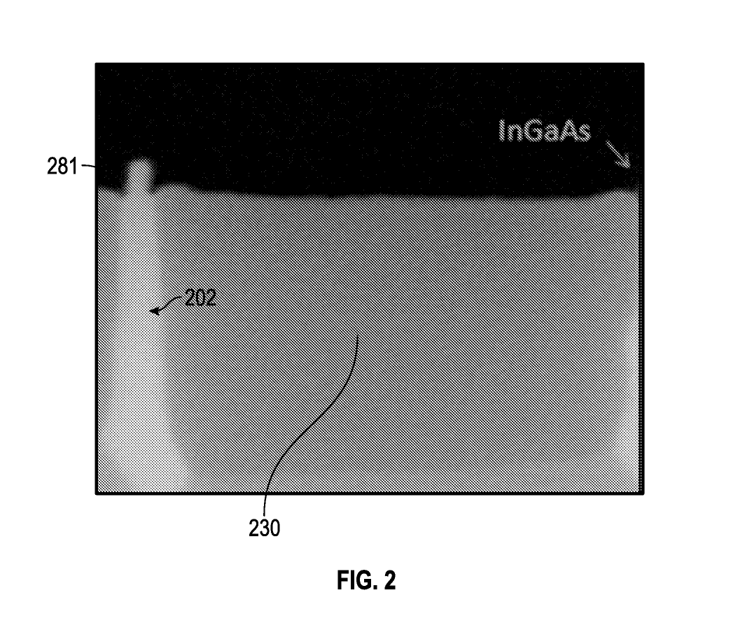

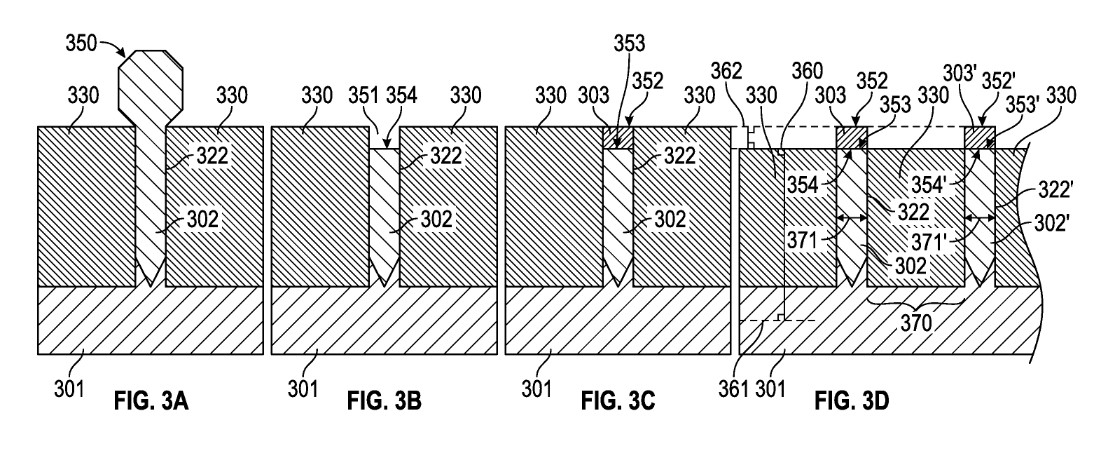

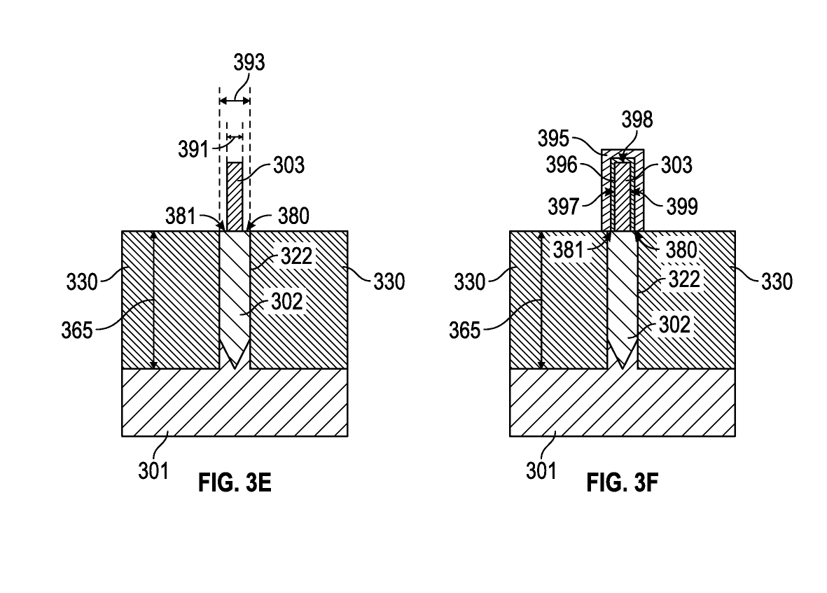

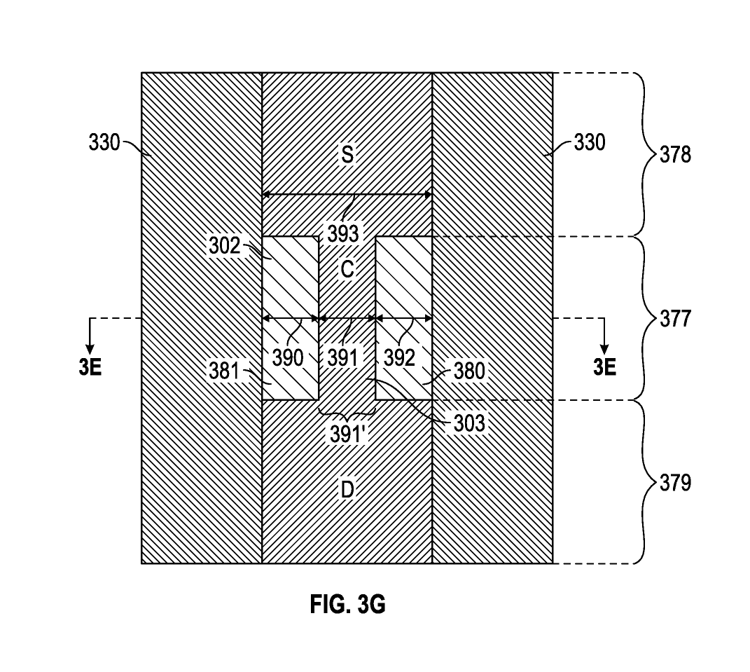

FIG. 1 includes a method 100 in an embodiment of the invention. FIG. 2 includes an image of an embodiment of the invention. FIGS. 3(a)-(g) show views of embodiments of the invention at various processing stages. These figures are discussed below.

Block of 105 of FIG. 1 includes forming a trench within an insulation layer and on a substrate. Block 110 includes forming a fin, which includes a III-V material, within the trench (with a portion 350 of the fin extending over the trench). For example, FIG. 3(a) depicts growth of an InP fin 302 (although other embodiments may use other III-V materials), which will eventually serve as subfin support for channel material. Fin 302 is grown on substrate 301 and within ART trench 322 and STI 330.

Block 115 includes polishing the portion 350 of the fin that extends over the trench to a level generally coplanar with a top surface of the insulation layer 330. Block 120 includes removing an upper portion of the fin, located within the trench, to provide a recess 351 within the trench extending downwards to an upper surface 354 of the fin remainder. For example, overgrowth 350 is removed in FIG. 3(b) via InP polishing and InP is further recessed to form recess 351 above subfin portion 302.

Block 125 includes forming a III-V material within the recess and directly on the upper surface of the fin remainder to form a fin structure including a fin lower portion, which includes the fin remainder, and a fin upper portion, which includes the III-V material. For example, in FIG. 3(c) InGaAs 303 is grown within trench 322 and polished to form a flat upper surface 352 and flat lower surface 353 formed atop flat upper surface 354.

Block 130 includes removing a portion of the insulation layer adjacent side walls of the fin upper portion. For example, in FIG. 3(d) STI 330 is recessed to expose InGaAs layer 303. FIG. 3(d) further includes a second fin adjacent to the fin that was the focus of FIGS. 3(a)-(c). Specifically, FIG. 3(d) depicts a device comprising: a first fin structure including a first upper fin portion 303 on a first lower fin portion 302 and a second fin structure including a second upper fin portion 303′ on a second lower fin portion 302′. No other fin structures exist between the first and second fin structures (i.e., within area 370) and first and second fin structures are adjacent one another. The first and second upper fin portions 303, 303′ have first and second bottom surfaces 353, 353′ that directly contact first and second upper surfaces 354, 354′ of the first and second lower fin portions 302, 302′. The first and second bottom surfaces 353, 353′ are generally coplanar with one another and are generally flat. For example, first and second bottom surfaces 353, 353′ are each located along horizontal line 360, which is parallel to long axis (horizontal) 361 of substrate 301. The first and second upper surfaces 354, 354′ are generally coplanar with one another and are generally flat (first and second upper surfaces 354, 354′ are each located on line 360). The first and second upper fin structures 303, 303′ include an upper III-V material and the first and second lower fin structures 302, 302′ include a lower III-V material different from the upper III-V material. For example, while many embodiments herein describe 303/302 stacks of InGaAs/InP other embodiments are not so limited and may include, for example, InGaAs/InAlAs, InGaAs/InAlAs/InP, or InGaAs/InP/InAlAs (e.g., where InGaAs includes InₓGa₁₋ₓAs where x is between 0 and 1 and where InAlAs includes InₓAl₁₋ₓAs where x is between 0 and 1). In an embodiment stack layers 303/302 and 303′/302′ are epitaxial layers.

The first and second fin structures are at least partially included in first and second trenches 322, 322′. In an embodiment the first and second trenches each have generally equivalent aspect ratios (depth to width) that are at least 2:1. Embodiments may include ratios including 1.5:1, 2.5:1, 3:1 (150 nm: 50 nm); 4:1 and the like.

In an embodiment, the first and second upper fin portions 303, 303′ have first and second top surfaces that are generally coplanar with one another, are generally flat (top surfaces 352, 352′ are each located on line 362), and are generally parallel to the substrate (see line 361) and to the first and second bottom surfaces 353, 353′. Top surfaces 352, 352′ may be flat/planar due to polishing.

In an embodiment, the first and second bottom surfaces 353, 353′ are flat and each extend across entire breadths 371, 371′ of the first and second fin structures.

Block 135 includes removing lateral portions of the fin upper portion (using a mixture of hydroxy-acid and peroxide) so the fin upper portion has a bottom surface with a bottom maximum width and the fin lower portion has an upper surface with an upper maximum width that is greater the bottom maximum width. In an embodiment a dilute hydroxy-acid/peroxide aqueous non-aqueous mixture (e.g., citric acid 10% to 80 wt % and hydrogen peroxide from 1% to wt 30%) is used to etch the upper portion (e.g., InGaAs portion).

For example, FIG. 3(e) includes a side view after a portion of the fin has been thinned and FIG. 3(g) includes a top view after a portion of the fin has been thinned. FIGS. 3(e) and 3(g) include a device comprising a fin structure including an upper portion (InGaAs portion 303) and a lower portion (InP portion 302), the upper portion 303 having a bottom surface 353 directly contacting an upper surface 354 of the lower portion 302. The lower portion 302 is included in a trench 322 having an aspect ratio (depth to width) of at least 2:1. Thus the depth 365 is at least 2:1 over width 393; however in other embodiments the ratio is 3:1, 4:1, 5:1, and the like. In an embodiment the bottom surface 353 has a bottom maximum width 391 and the upper surface has an upper maximum width 393 that is greater than the bottom maximum width 391. In an embodiment the bottom surface 353 covers a middle portion 391′ of the upper surface 354 but does not cover lateral portions 380 (having a width 392), 381 (having a width 390) of the upper surface 354. The upper portion 303 includes an upper III-V material and the lower portion 302 includes a lower III-V material different from the upper III-V material. In an embodiment the upper III-V material includes InₓGa₁₋ₓAs, where x is between 0 and 100, and the lower III-V material includes InP.

FIG. 2 includes an image of subfin 202 (InP), within STI 230 and below channel material 203 (InGaAs). Channel material 203 has been narrowed revealing surfaces 281, 200.

Block 140 includes forming a gate on side and top surfaces of the fin upper portion. For example, FIG. 3(f) includes a gate formed on side surfaces 397, 399 and top surface 398 of the upper portion 303. The gate directly contacts the lateral portions 380, 381 of the upper surface 354. In an embodiment, the gate includes a gate material 395 including at least one of a metal and polysilicon and the gate further includes a gate dielectric 396, and at least one of the gate dielectric and the gate material directly contacts the lateral portions 380, 381 of the upper surface. In the case of FIG. 3(f) both gate material 395 and gate dielectric 396 contact lateral portions 380, 381.

In an embodiment, the bottom maximum width 391 is not greater than 20 nm and the upper maximum width 393 is not less than 4 nm.

In an embodiment, the lower portion 302 directly contacts substrate 301 (e.g., a Si substrate) included in the device. However, in other embodiments a layer or layers are between portion 302 and substrate 301.

In an embodiment, the bottom surface 353 is included in a channel (C) of a transistor. For example, in an embodiment the channel is located in an area 377 of the upper portion 303 that is thinner than areas 378, 379 of the upper portion 303 that include a source (S) and a drain (D) corresponding to the channel (C).

Various embodiments include a semiconductive substrate. Such a substrate may be a bulk semiconductive material this is part of a wafer. In an embodiment, the semiconductive substrate is a bulk semiconductive material as part of a chip that has been singulated from a wafer. In an embodiment, the semiconductive substrate is a semiconductive material that is formed above an insulator such as a semiconductor on insulator (SOI) substrate. In an embodiment, the semiconductive substrate is a prominent structure such as a fin that extends above a bulk semiconductive material.

The following examples pertain to further embodiments.

Example 1 includes a device comprising: a fin structure including an upper portion and a lower portion, the upper portion having a bottom surface directly contacting an upper surface of the lower portion; wherein (a) the lower portion is included in a trench having an aspect ratio (depth to width) of at least 2:1; (b) the bottom surface has a bottom maximum width and the upper surface has an upper maximum width that is greater the bottom maximum width; (c) the bottom surface covers a middle portion of the upper surface but does not cover lateral portions of the upper surface; and (d) the upper portion includes an upper III-V material and the lower portion includes a lower III-V material different from the upper III-V material.

In example 2 the subject matter of example 1 can optionally include wherein the upper III-V material includes InₓGa₁₋ₓAs, where x is between 0 and 1, and the lower III-V material includes InP.

In example 3 the subject matter of examples 1-2 can optionally include a gate formed on side and top surfaces of the upper portion.

In example 4 the subject matter of examples 1-3 can optionally include wherein the gate directly contacts the lateral portions of the upper surface.

In example 5 the subject matter of examples 1-4 can optionally include wherein: (a) the gate includes a gate material including at least one of a metal and polysilicon and the gate further includes a gate dielectric, and (b) at least one of the gate dielectric and the gate material directly contacts the lateral portions of the upper surface.

In example 6 the subject matter of examples 1-5 can optionally include wherein the bottom maximum is width is not greater than 20 nm and the upper maximum width is not less than 2 nm.

In example 7 the subject matter of examples 1-6 can optionally include wherein the III-V material has an upper energy bandgap and the InP has a lower energy bandgap greater than the upper energy bandgap.

In example 8 the subject matter of examples 1-7 can optionally include wherein the lower portion directly contacts a substrate included in the device.

In example 9 the subject matter of examples 1-8 can optionally include wherein the substrate includes Si.

In example 10 the subject matter of examples 1-9 can optionally include wherein the bottom surface includes InGaAs and the upper surface InP.

In example 11 the subject matter of examples 1-10 can optionally include wherein the bottom surface is included in a channel of a transistor.

In example 12 the subject matter of examples 1-11 can optionally include wherein the channel is located in an area of the upper portion that is thinner than an addition area of the upper portion that includes one of a source and a drain corresponding to the channel.

In example 13 the subject matter of examples 1-12 can optionally include wherein the III-V material and the InP are both included in epitaxial layers.

Example 14 includes a method comprising: forming a trench within an insulation layer and on a substrate; forming a fin, which includes InP, within the trench with a portion of the fin extending over the trench; polishing the portion of the fin that extends over the trench to a level generally coplanar with a top surface of the insulation layer; removing an upper portion of the fin, located within the trench, to provide a recess within the trench extending downwards to an upper surface of the fin remainder; forming a III-V material within the recess and directly on the upper surface of the fin remainder to form a fin structure including a fin lower portion, which includes the fin remainder, and a fin upper portion, which includes the III-V material; removing a portion of the insulation layer adjacent side walls of the fin upper portion; and removing lateral portions of the fin upper portion so the fin upper portion has a bottom surface with a bottom maximum width and the fin lower portion has an upper surface with an upper maximum width that is greater the bottom maximum width.

In example 15 the subject matter of example 14 can optionally include wherein (a) the fin lower portion is included in a trench portion having an aspect ratio (depth to width) of at least 2:1.

In example 16 the subject matter of examples 14-15 can optionally include wherein the bottom surface of the fin upper portion covers a middle portion of the upper surface of the fin lower portion but does not cover lateral portions of the upper surface of the fin lower portion.

In example 17 the subject matter of examples 14-16 can optionally include wherein the III-V material includes InGaAs.

In example 18 the subject matter of examples 14-17 can optionally include forming a gate on side and top surfaces of the fin upper portion.

In example 19 the subject matter of examples 14-18 can optionally include wherein the bottom maximum is width is not greater than 20 nm and the upper maximum width is not less than 4 nm.

In example 20 the subject matter of examples 16-19 can optionally include wherein the fin lower portion directly contacts the substrate.

In example 21 the subject matter of examples 16-20 can optionally include wherein removing lateral portions of the fin upper portion includes etching the lateral portions of the fin upper portion with a mixture of hydroxy-acid and peroxide.

Example 22 includes a device comprising: a fin structure including upper and lower portions, the upper portion having a bottom surface directly contacting an upper surface of the lower portion; wherein (a) the lower portion is included in a trench; (b) the bottom surface has a bottom maximum width wider than an upper maximum width of the upper surface; (c) the bottom surface covers a middle portion of the upper surface but not lateral portions of the upper surface; and (d) upper portion includes a III-V material and the lower portion includes InP.

Another version of example 22 includes a device comprising: a fin structure including upper and lower portions, the upper portion having a bottom surface directly contacting an upper surface of the lower portion; wherein (a) the lower portion is included in a trench; (b) the bottom surface has a bottom maximum width wider than an upper maximum width of the upper surface; (c) the bottom surface covers a middle portion of the upper surface but not lateral portions of the upper surface; and (d) the upper portion includes an upper III-V material and the lower portion includes a lower III-V material different from the upper III-V material.

In example 23 the subject matter of example 22 can optionally include wherein the upper III-V material includes InxGa1−xAs, where x is between 0 and 1, and the lower III-V material includes InP.

In example 24 the subject matter of examples 22-23 can optionally include wherein the bottom maximum is width is not greater than 20 nm and the upper maximum width is not less than 4 nm.

In example 25 the subject matter of examples 22-24 can optionally include wherein the lower portion directly contacts a substrate included in the device.

The foregoing description of the embodiments of the invention has been presented for the purposes of illustration and description. It is not intended to be exhaustive or to limit the invention to the precise forms disclosed. This description and the claims following include terms, such as left, right, top, bottom, over, under, upper, lower, first, second, etc. that are used for descriptive purposes only and are not to be construed as limiting. For example, terms designating relative vertical position refer to a situation where a device side (or active surface) of a substrate or integrated circuit is the “top” surface of that substrate; the substrate may actually be in any orientation so that a “top” side of a substrate may be lower than the “bottom” side in a standard terrestrial frame of reference and still fall within the meaning of the term “top.” The term “on” as used herein (including in the claims) does not indicate that a first layer “on” a second layer is directly on and in immediate contact with the second layer unless such is specifically stated; there may be a third layer or other structure between the first layer and the second layer on the first layer. The embodiments of a device or article described herein can be manufactured, used, or shipped in a number of positions and orientations. Persons skilled in the relevant art can appreciate that many modifications and variations are possible in light of the above teaching. Persons skilled in the art will recognize various equivalent combinations and substitutions for various components shown in the Figures. It is therefore intended that the scope of the invention be limited not by this detailed description, but rather by the claims appended hereto.

What is claimed is:

1. A device comprising:
a fin structure including an upper portion and a lower portion, the upper portion having a bottom surface directly contacting an upper surface of the lower portion;
wherein (a) the lower portion is included in a trench having an aspect ratio (depth to width) of at least 2:1; (b) the bottom surface has a bottom maximum width and the upper surface has an upper maximum width that is greater the bottom maximum width; (c) the bottom surface covers a middle portion of the upper surface but does not cover lateral portions of the upper surface; and (d) the upper portion includes an upper III-V material and the lower portion includes a lower III-V material different from the upper III-V material.

2. The device of claim 1, wherein the upper III-V material includes InₓGa₁₋ₓAs, where x is between 0 and 1, and the lower III-V material includes InP.

3. The device of claim 1, including a gate formed on side and top surfaces of the upper portion.

4. The device of claim 3, wherein the gate directly contacts the lateral portions of the upper surface.

5. The device of claim 4, wherein: (a) the gate includes a gate material including at least one of a metal and polysilicon and the gate further includes a gate dielectric, and (b) at least one of the gate dielectric and the gate material directly contacts the lateral portions of the upper surface.

6. The device of claim 1, wherein the bottom maximum is not greater than 20 nm and the upper maximum width is not less than 4 nm.

7. The device of claim 1 wherein the III-V material has an upper energy bandgap and the InP has a lower energy bandgap greater than the upper energy bandgap.

8. The device of claim 1 wherein the lower portion directly contacts a substrate included in the device.

9. The device of claim 8, wherein the substrate includes Si.

10. The device of claim 1, wherein the bottom surface includes InGaAs and the upper surface InP.

11. The device of claim 1, wherein the bottom surface is included in a channel of a transistor.

12. The device of claim 11, wherein the channel is located in an area of the upper portion that is thinner than an addition area of the upper portion that includes one of a source and a drain corresponding to the channel.

13. The device of claim 1, wherein the III-V material and the InP are both included in epitaxial layers.

14. A method comprising:
forming a trench within an insulation layer and on a substrate;
forming a fin, which includes InP, within the trench with a portion of the fin extending over the trench;
polishing the portion of the fin that extends over the trench to a level generally coplanar with a top surface of the insulation layer;
removing an upper portion of the fin, located within the trench, to provide a recess within the trench extending downwards to an upper surface of the fin remainder;
forming a III-V material within the recess and directly on the upper surface of the fin remainder to form a fin structure including a fin lower portion, which includes the fin remainder, and a fin upper portion, which includes the III-V material;
removing a portion of the insulation layer adjacent side walls of the fin upper portion; and
removing lateral portions of the fin upper portion so the fin upper portion has a bottom surface with a bottom maximum width and the fin lower portion has an upper surface with an upper maximum width that is greater the bottom maximum width.

15. The method of claim 14, wherein (a) the fin lower portion is included in a trench portion having an aspect ratio (depth to width) of at least 2:1.

16. The method of claim 14, wherein the bottom surface of the fin upper portion covers a middle portion of the upper surface of the fin lower portion but does not cover lateral portions of the upper surface of the fin lower portion.

17. The method of claim 14, wherein the III-V material includes InGaAs.

18. The method of claim 14 comprising forming a gate on side and top surfaces of the fin upper portion.

19. The method of claim 14, wherein the bottom maximum is width is not greater than 20 nm and the upper maximum width is not less than 4 nm.

20. The method of claim 14, wherein the fin lower portion directly contacts the substrate.

21. The method of claim 14, wherein removing lateral portions of the fin upper portion includes etching the lateral portions of the fin upper portion with a mixture of hydroxy-acid and peroxide.

22. A device comprising:
a fin structure including upper and lower portions, the upper portion having a bottom surface directly contacting an upper surface of the lower portion;
wherein (a) the lower portion is included in a trench; (b) the bottom surface has a bottom maximum width wider than an upper maximum width of the upper surface; (c) the bottom surface covers a middle portion of the upper surface but not lateral portions of the upper surface; and (d) the upper portion includes an upper III-V material and the lower portion includes a lower III-V material different from the upper III-V material.

23. The device of claim 22, wherein the upper III-V material includes InₓGa₁₋ₓAs, where x is between 0 and 1, and the lower III-V material includes InP.

24. The device of claim 22, wherein the bottom maximum is width is not greater than 20 nm and the upper maximum width is not less than 4 nm.

25. The device of claim 22 including a gate formed on side and top surfaces of the upper portion, wherein the gate directly contacts the lateral portions of the upper surface.
